(19) United States
(12) Patent Application Publication
(10) Pub. No.: US 2014/0199823 A1
(43) Pub. Date: Jul. 17, 2014

(54) METHOD FOR MANUFACTURING SEMICONDUCTOR DEVICE

(71) Applicants: Noritsugu Nomura, Tokyo (JP); Akira Okada, Tokyo (JP); Tatsuo Harada, Tokyo (JP)

(72) Inventors: Noritsugu Nomura, Tokyo (JP); Akira Okada, Tokyo (JP); Tatsuo Harada, Tokyo (JP)

(73) Assignee: MITSUBISHI ELECTRIC CORPORATION, Tokyo (JP)

(21) Appl. No.: 14/110,690

(22) PCT Filed: Jun. 10, 2011
(86) PCT No.: PCT/JP2011/063355

§ 371 Date: Oct. 8, 2013

(51) Int. Cl. H01L 21/762

(52) U.S. Cl. CPC H01L 21/76254
USPC 438/458

(57) ABSTRACT

An SOT substrate (6), in which a silicon layer (5) is provided on a silicon substrate (3) via a silicon oxide film (4), is formed. Next, a plurality of semiconductor elements (8) is formed on a surface of the silicon layer (5). Next, wiring (11) is formed on a surface of an insulating substrate (10). Next, the SOI substrate (6) and the insulating substrate (10) are pasted together so that the plurality of semiconductor elements (8) and the wiring (11) are electrically connected together. Next, at least one of hydrogen ions and rare gas ions are injected into the silicon substrate (3) to form a brittle layer (12). Next, part of the silicon substrate (3) is peeled away from the brittle layer (12) as a boundary.

### TECHNICAL FIELD

The present invention relates to a method for manufacturing a semiconductor device including a SOI (Silicon On Insulator) substrate.

### BACKGROUND ART

In the field of LSI, SOI substrates are known which are two wafers pasted together as wafers for high performance devices. According to a conventional method of forming this SOI substrate, a silicon oxide film is formed on at least one of two mirror-polished wafers first. Next, the two wafers are brought into close contact with each other via the silicon oxide film and subjected to heat treatment to increase bonding strength. Next, the wafer on which a device is formed is ground and mirror-polished to reduce its thickness to a desired thickness. An SOI substrate containing a silicon oxide film (BOX layer) is formed in this way.

A method of forming an SOI substrate called a “smart-cut (registered trademark)” method is known in recent years. According to this method, a silicon oxide film is formed on at least one of two mirror-polished wafers first. Next, hydrogen ions are injected into the wafer on which a device is formed and a brittle layer is thereby formed. Next, the two wafers are brought into close contact with each other via the silicon oxide film and subjected to heat treatment to increase bonding strength. Next, part of the wafer is peeled away from the brittle layer as a boundary. Next, the surface of the wafer is polished. An SOI substrate is formed in this way.

This method can reduce the process temperature and manufacturing cost more than the conventional method. Furthermore, by adjusting the depth of injection of hydrogen ions, it is possible to freely adjust the thickness of a silicon layer formed on the silicon oxide film.

Furthermore, a semiconductor device with a silicon substrate pasted to an insulating substrate is proposed (e.g., see Patent Literature 1). This can reduce the manufacturing cost and increase a withstand voltage.

Furthermore, a semiconductor device is disclosed whose overall wafer thickness is reduced to reduce on resistance or thermal resistance (e.g., see Patent Literature 2). However, since the wafer whose overall thickness is reduced has less substrate strength, it is difficult to handle such a wafer. Thus, to secure sufficient substrate strength, a manufacturing method for reducing the thickness of a wafer element portion alone is disclosed (e.g., see Patent Literature 3).

### CITATION LIST

### Patent Literature

Patent Literature 1: Japanese Patent Laid-Open No. 2000-77548

Patent Literature 2: Japanese Patent Laid-Open No. 2005-303218

Patent Literature 3: Japanese Patent Laid-Open No. 2011-3568

### SUMMARY OF INVENTION

### Technical Problem

Since the semiconductor device described in Patent Literature 1 is of a horizontal type, it has been not possible to implement a semiconductor device with high current and low on resistance. Changing the semiconductor device described in Patent Literature 1 to a thinner and vertical type device would increase its manufacturing cost.

Since the manufacturing steps in Patent Literatures 2 and 3 are complicated, their manufacturing costs are high. Moreover, since the wafer thickness is reduced only by grinding, a defect may occur on the ground surface of the silicon layer. Although the step of thinning the SOI substrate by etching is also disclosed, the member removed by etching cannot be reused, resulting in an increase in the manufacturing cost.

In view of the above-described problems, an object of the present invention is to provide a method for manufacturing a semiconductor device which can improve performance and reduce the manufacturing cost.

### Means for Solving the Problems

According to the present invention, a method for manufacturing a semiconductor device comprises: forming an SOI substrate in which a silicon layer is provided on a silicon substrate via a silicon oxide film; forming a plurality of semiconductor elements on a surface of the silicon layer; forming wiring on a surface of an insulating substrate; pasting the SOI substrate and the insulating substrate together so that the plurality of semiconductor elements and the wiring are electrically connected together; after pasting the SOI substrate and the insulating substrate, injecting at least one of hydrogen ions and rare gas ions into the silicon substrate to form a brittle layer; and peeling part of the silicon substrate away from the brittle layer as a boundary.

### Effect of Invention

The present invention makes it possible to improve performance and reduce the manufacturing cost.

### BRIEF DESCRIPTION OF THE DRAWINGS

FIG. 1 is a sectional view for explaining a method for manufacturing a semiconductor device according to the embodiment of the present invention.

FIG. 2 is a sectional view for explaining a method for manufacturing a semiconductor device according to the embodiment of the present invention.

FIG. 3 is a sectional view for explaining a method for manufacturing a semiconductor device according to the embodiment of the present invention.

FIG. 4 is a sectional view for explaining a method for manufacturing a semiconductor device according to the embodiment of the present invention.

FIG. 5 is a sectional view for explaining a method for manufacturing a semiconductor device according to the embodiment of the present invention.

FIG. 6 is a sectional view for explaining a method for manufacturing a semiconductor device according to the embodiment of the present invention.

FIG. 7 is a sectional view for explaining a method for manufacturing a semiconductor device according to the embodiment of the present invention.

FIG. 8 is a sectional view for explaining a method for manufacturing a semiconductor device according to the embodiment of the present invention.

FIG. 9 is a sectional view for explaining a method for manufacturing a semiconductor device according to the embodiment of the present invention.

FIG. 10 is a sectional view for explaining a method for manufacturing a semiconductor device according to the embodiment of the present invention.

FIG. 11 is a sectional view for explaining a method for manufacturing a semiconductor device according to the embodiment of the present invention.

FIG. 12 is a sectional view for explaining a method for manufacturing a semiconductor device according to the embodiment of the present invention.

FIG. 13 is a sectional view for explaining a method for manufacturing a semiconductor device according to the embodiment of the present invention.

### DESCRIPTION OF EMBODIMENTS

A method for manufacturing a semiconductor device according to the embodiment of the present invention will be described with reference to the drawings. The same components will be denoted by the same symbols, and the repeated description thereof may be omitted.

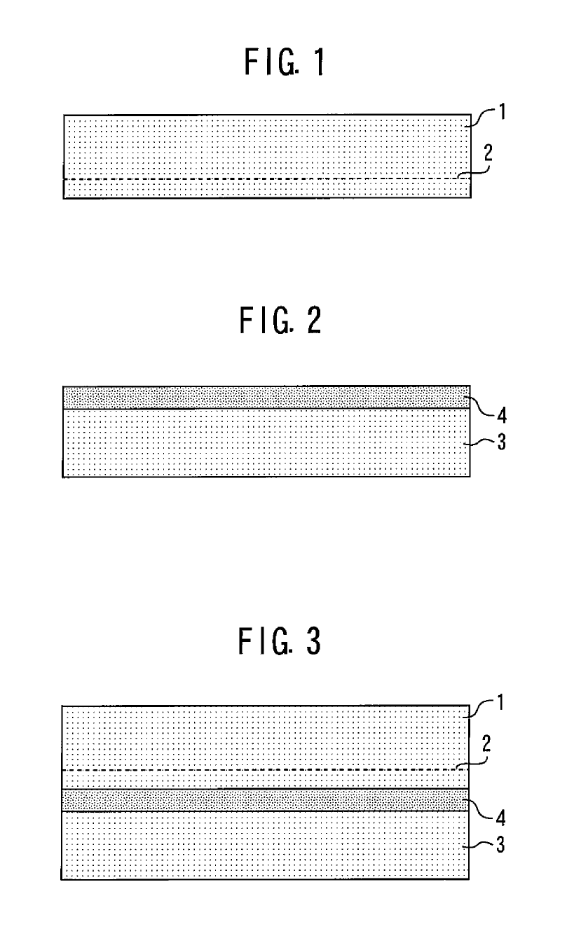

First, as shown in FIG. 1, hydrogen ions are injected into a silicon substrate 1 to form a brittle layer 2. Ions used are not limited to hydrogen ions but may be rare gas ions or both hydrogen ions and rare gas ions.

Next, as shown in FIG. 2, a silicon oxide film 4 is formed on a silicon substrate 3 using a thermal oxidation method. The method of forming the silicon oxide film 4 is not limited to the thermal oxidation method.

Next, as shown in FIG. 3, the silicon substrate 1 and the silicon substrate 3 are pasted together via the silicon oxide film 4. Both substrates are brought into close contact with each other and subjected heat treatment to increase bonding strength. This heat treatment produces bubbles of a hydrogen gas in the brittle layer 2.

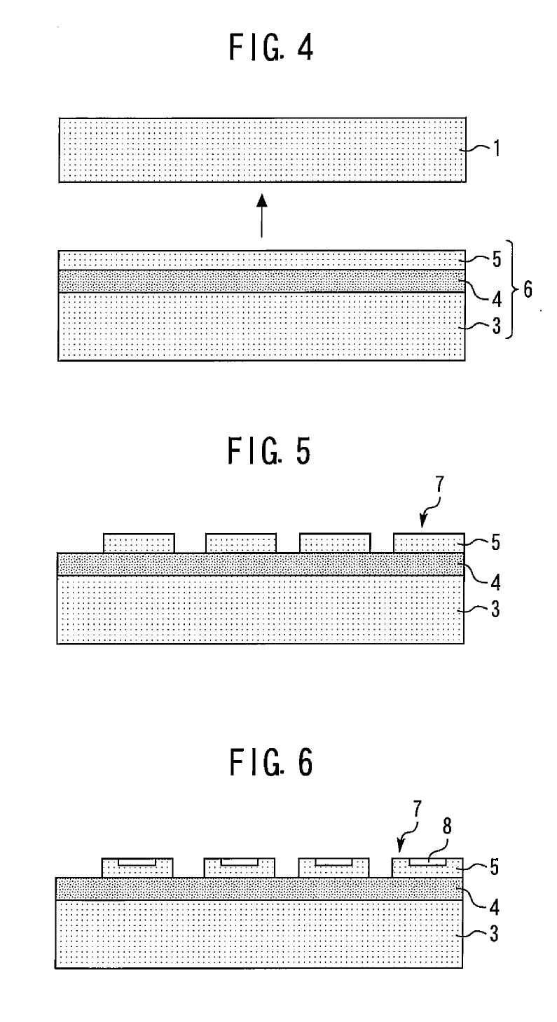

Next, as shown in FIG. 4, part of the silicon substrate 1 is peeled away from the brittle layer 2 as a boundary. Thus, an SOI substrate 6 is formed in which a silicon layer 5 is provided on the silicon substrate 3 via the silicon oxide film 4. If the depth of the brittle layer 2 is changed by adjusting the energy of injection of hydrogen ions, it is possible to adjust the thickness of the silicon layer 5.

Next, as shown in FIG. 5, the silicon layer 5 is separated into a plurality of islands 7 by patterning and etching. In this case, the silicon oxide film 4 arranged beneath the silicon layer 5 is used as an etching stop layer.

Next, as shown in FIG. 6, a plurality of semiconductor elements 8 are formed on the surface of the silicon layer 5 in the plurality of islands 7 respectively. The plurality of semiconductor elements 8 are ICs (Integrated Circuits), IGBTs (Insulated Gate Bipolar Transistors), diodes or the like, but the semiconductor elements 8 are not limited to these.

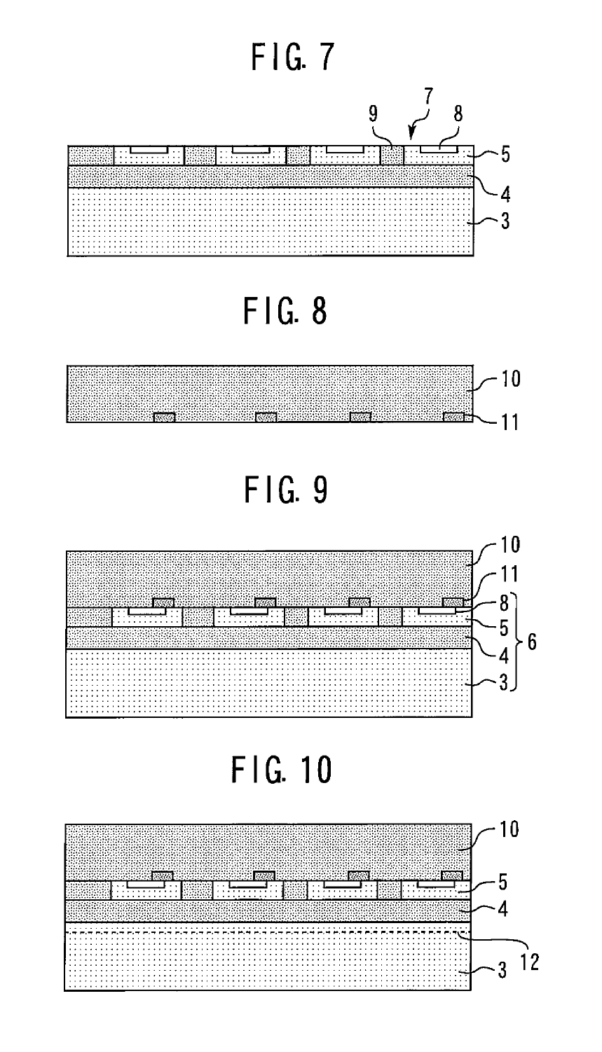

Next, as shown in FIG. 7, dielectric 9 is applied to the entire surface, then flattened by CMP, and the dielectric 9 is thereby embedded between the plurality of islands 7.

Next, as shown in FIG. 8, wiring 11 is formed on the surface of an insulating substrate 10. The insulating substrate 10 is made of a material having mechanical strength such as glass or ceramics.

Next, as shown in FIG. 9, the SOI substrate 6 and the insulating substrate 10 are mechanically pasted together so that the plurality of semiconductor elements 8 and wiring 11 are electrically connected together via solder bumps or the like.

Next, as shown in FIG. 10, hydrogen ions are injected into the back side of the silicon substrate 3 to form a brittle layer 12. Ions to be injected are not limited to hydrogen ions, but may be rare gas ions or both hydrogen ions and rare gas ions.

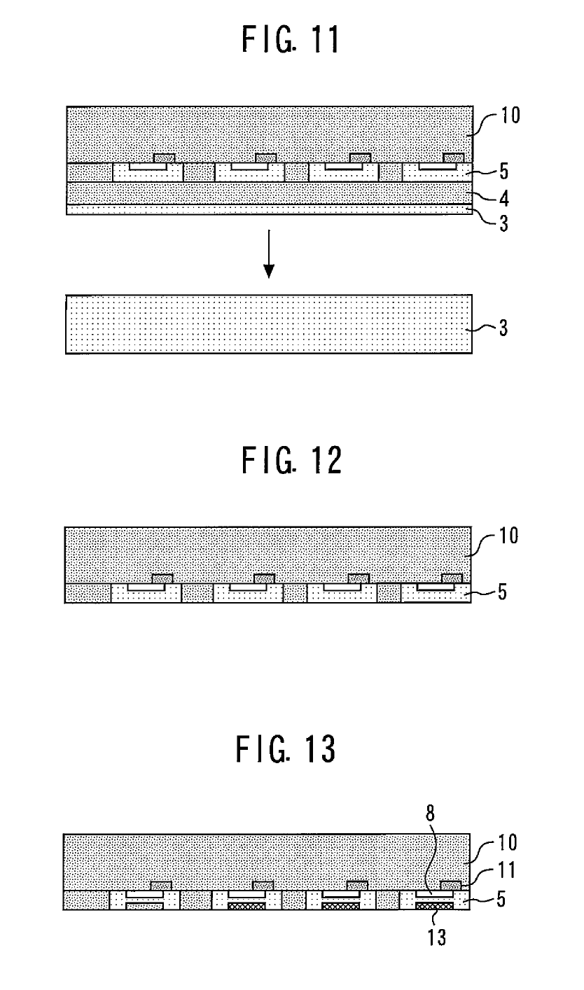

Next, when subjected to heat treatment, bubbles of a hydrogen gas are produced in the brittle layer 12. As shown in FIG. 11, part of the silicon substrate 3 is peeled away from this brittle layer 12 as a boundary.

Next, as shown in FIG. 12, the remainder of the silicon substrate 3 and the silicon oxide film 4 are removed by grinding or etching. Note that when all layers are removed by only grinding such as CMP (Chemical Mechanical Polishing), a defect may occur in the exposed silicon layer 5. Therefore, the silicon oxide film 4 is preferably removed by etching.

Next, as shown in FIG. 13, an impurity diffusion layer 13 and an electrode or the like are formed on the back side of the silicon layer 5. For example, a collector layer of an IGBT is formed using impurity injection and partial activity, and further a collector electrode is formed. As a result, a vertical type semiconductor device such as an IGBT is formed in the silicon layer 5.

Next, effects of the present embodiment will be described. In the present embodiment, on resistance or thermal resistance can be reduced by peeling away part of the silicon substrate 3 and thereby thinning the substrate. Furthermore, the withstand voltage can be improved by pasting the insulating substrate 10 to the SOI substrate 6. As a result, performance of the semiconductor device can be improved.

Furthermore, in the present embodiment, after pasting the SOI substrate 6 to the insulating substrate 10, part of the silicon substrate 3 is peeled away. Therefore, since the insulating substrate 10 supports the thin silicon layer 5 on which the semiconductor element 8 is formed, it is easy to handle the device after the peeling. Furthermore, part of the peeled silicon substrate 3 can be reused. Similarly, part of the silicon substrate 1 peeled away when forming the SOI substrate 6 can also be reused. Furthermore, by pasting the insulating substrate 10 on which the wiring 11 is formed beforehand, the wiring no longer remains, and the subsequent steps can be omitted. As a result, the manufacturing cost can be reduced.

Furthermore, when the silicon substrate 3 and the silicon oxide film 4 are all ground, a defect occurs on the back side of the silicon layer 5. By contrast, in the present embodiment, after part of the silicon substrate 3 is peeled away, the remainder of the silicon substrate 3 and the silicon oxide film 4 are removed by grinding or etching. This makes it possible to suppress the defect on the back side of the silicon layer 5. Furthermore, it is also possible to form the impurity diffusion layers 13 and electrodes of the plurality of semiconductor elements 8 on the back side of the exposed silicon layer 5 at once. The manufacturing cost can thereby be reduced.

Furthermore, in the present embodiment, the plurality of islands 7 on which the plurality of semiconductor elements 8 are formed are discretely insulated by the dielectric 9. This makes it possible to eliminate mutual influences between the semiconductor elements 8 and improve the withstand voltage.

Furthermore, when the plurality of semiconductor elements 8 are separated by trenches, the semiconductor elements 8 may not be reliably separated due to a variation in the trench depth. By contrast, in the present embodiment, the silicon layer 5 is separated into the plurality of islands 7 by etching using the silicon oxide film 4 as an etching stop layer. This allows the plurality of semiconductor elements 8 to be reliably separated.

### REFERENCE SIGNS LIST

3 Silicon substrate

4 Silicon oxide film

5 Silicon layer

6 SOI substrate

8 Semiconductor element

9 Dielectric

10 Insulating substrate

11 Wiring

12 Brittle layer

13 Impurity diffusion layer

1-3. (canceled)

4. A method for manufacturing a semiconductor device comprising:
forming an SOI substrate in which a silicon layer is provided on a silicon substrate via a silicon oxide film;
forming a plurality of semiconductor elements on a surface of the silicon layer;
forming wiring on a surface of an insulating substrate;
pasting the SOI substrate and the insulating substrate together so that the plurality of semiconductor elements and the wiring are electrically connected together;
after pasting the SOI substrate and the insulating substrate, injecting at least one of hydrogen ions and rare gas ions into the silicon substrate to form a brittle layer; and
peeling part of the silicon substrate away from the brittle layer as a boundary.

5. The method for manufacturing a semiconductor device according to claim 4, further comprising:
after peeling part of the silicon substrate away, removing a remainder of the silicon substrate and the silicon oxide film by grinding or etching; and
after removing the silicon substrate and the silicon oxide film, forming an impurity diffusion layer on a back side of the silicon layer.

6. The method for manufacturing a semiconductor device according to claim 4, further comprising:
separating the silicon layer into a plurality of islands by etching using the silicon oxide film as an etching stop layer;
forming the plurality of semiconductor elements in the plurality of islands respectively; and
embedding a dielectric between the plurality of islands.
